(19) United States
(12) Patent Application Publication
(10) Pub. No.: US 2015/0056772 A1
(43) Pub. Date: Feb. 26, 2015

(54) SEMICONDUCTOR DEVICE COMPRISING BURIED GATE AND METHOD FOR FABRICATING THE SAME

(71) Applicant: SK hynix Inc., Gyeonggi-do (KR)

(72) Inventors: Jung-Nam KIM, Gyeonggi-do (KR); Sang-Soo KIM, Gyeonggi-do (KR)

(73) Assignee: SK hynix Inc.

(21) Appl. No.: 14/532,762

(22) Filed: Nov. 4, 2014

Related U.S. Application Data
(62) Division of application No. 13/711,389, filed on Dec. 11, 2012.

(30) Foreign Application Priority Data
Aug. 31, 2012 (KR) 10-2012-0096405

(51) Int. Cl. H01L 29/66; H01L 21/321; H01L 21/3205; H01L 29/423; H01L 29/45

(52) U.S. Cl. CPC H01L 29/66621; H01L 29/4236; H01L 29/45; H01L 21/32053; H01L 21/321; H01L 29/665
USPC 438/270

(57) ABSTRACT

The present invention provides a semiconductor device including a buried gate and a method for fabricating the same, in which the width of a contact plug may not exceed a predetermined width. The method including forming a plurality of trenches over a substrate using the mask pattern, forming a gate insulating film in each of the plurality of trenches, forming a plurality of gate electrodes filling portions of the plurality of trenches, removing an exposed gate insulating film formed over each of the plurality of gate electrodes in each of the plurality of the trenches, forming a plurality of sealing films filling remaining portions of the plurality of trenches, and forming a plurality of contact plugs over the substrate between the trenches.

### CROSS-REFERENCE TO RELATED APPLICATIONS

This application is a division of U.S. patent application Ser. No. 13/711,389 filed on Dec. 11, 2012, which claims priority of Korean Patent Application No. 10-2012-0096405, filed on Aug. 31, 2012. The disclosure of each of the foregoing application is incorporated herein by reference in its entirety.

### BACKGROUND

1. Field

Exemplary embodiments of the present invention relate to semiconductor device fabrication technology, and more particularly, to a semiconductor device including a buried gate and a method for fabricating the same.

2. Description of the Related Art

As the size of semiconductor devices is continuously reduced, it becomes more difficult to achieve various device characteristics and processes. Particularly, it is difficult to form gate structures, bit line strictures, contact structures or the like, which have a size of 40 nm or less, and even if the structures are formed, it is difficult to achieve the desired device characteristics. For this reason, a buried gate (BG) formed by burying a gate in a substrate was recently introduced.

FIGS. 1A to 1E are cross-sectional views for fabricating a semiconductor device including a buried gate according to the prior art.

As shown in FIG. 1A, a substrate 11 is etched using a mask pattern 12 as an etch barrier to form a plurality of trenches, and an oxidation process is performed to form a gate insulating film 14 over the entire surface. Because the oxidation process for forming the gate insulating film 14 is carried out by highly reactive oxidation such as radical oxidation, the surface of the mask pattern 12 is also oxidized.

As shown in FIG. 1B, a gate conductive film is formed on the gate insulating film 14 to fill the trenches, and then the entire surface of the resulting structure is etched, thereby forming gate electrodes 15. An insulating material having an etching selectivity different from the mask pattern 12 is deposited to fill the trenches 13. Then, a planarization process is carried out until the mask pattern 12 is exposed, thereby forming sealing films 16 on the gate electrodes 15, which fill the remaining portions of the trenches 13.

As shown in FIG. 1C, the mask pattern 12 is removed, thereby forming contact holes 17 in which contact plugs are formed, As the contact holes 17 are formed, the gate insulating film 14 formed on the sidewall of the sealing films 16 is partially exposed. The contact holes 17 have a first width CD1. Hereinafter, the exposed portion of the gate insulating film 14 will be indicated by the reference numeral 14A.

As shown in FIG. 1D, an impurity is ion-implanted into the substrate 11 through the contact holes 17 to form source/drain regions 18. Then, a cleaning process is carried out to remove oxides from the exposed surface of the substrate 11. In the cleaning process, the exposed gate insulating film 14A is also removed, and thus the contact holes 17 have a second width (CD2) larger than the first width CD1. Because the exposed gate insulating film 14A is damaged in the on implantation process, it is more easily removed in the cleaning process. Hereinafter, the contact holes 17 having the increased width will be indicated by the reference numeral 17A.

As shown in FIG. 1E, a conductive material is formed on the entire surface to fill the contact holes 17A, and then a planarization process is carried out until the sealing films 16 are exposed, thereby forming contact plugs 19.

In the above-described prior art, there is a problem in that, as the exposed gate insulating film 14A is removed by the cleaning process, the width of the contact holes 17A is increased to the second width CD2, which is wider than a predetermined width (i.e., first width CD1). For this reason, the contact plugs 19 have a width wider than a predetermined width.

The contact plugs 19 having a width wider than a predetermined width have concerns in that electrical interference (e.g., parasitic capacitance) between the adjacent contact plugs increases, which may result in deterioration in the device characteristics or a short circuit between the adjacent contact plugs 19. Another concern is the decrease in the overlay margin between the contact plugs and structures connected thereto, for example, bit lines or storage nodes for storing logic information.

### SUMMARY

Exemplary embodiments of the present invention are directed to a semiconductor device including a buried gate and a method for fabricating the same, in which the width of a contact plug may not exceed a predetermined width.

In accordance with an embodiment of the present invention, a method for fabricating a semiconductor device may include forming a plurality of trenches over a substrate, forming a gate insulating film in each of the plurality of trenches, forming a plurality of gate electrodes filling portions of the plurality of trenches, removing an exposed gate insulating film formed over each of the plurality of gate electrodes in each of the plurality of the trenches, forming a plurality of sealing films filling remaining portions of the plurality of trenches, and forming a plurality of contact plugs over the substrate between the trenches.

In accordance with another embodiment of the present invention, a semiconductor device may include a plurality of trenches formed in a substrate, a plurality of gate electrodes filling portions of the plurality of trenches, a gate insulating film interposed between each of the plurality of trenches and each of the plurality of gate electrodes, a plurality of sealing films formed over the plurality of gate electrodes to fill remaining portions of the plurality of trenches, and a plurality of contact plugs interposed between the plurality of sealing films protruding from the substrate, wherein each of the sealing films has a width larger than that of each of the gate electrodes.

### BRIEF DESCRIPTION OF THE DRAWINGS

FIGS. 1A to 1E are cross-sectional views illustrating a method for fabricating a semiconductor device including a buried gate according to the prior art.

FIG. 2 is a cross-sectional view illustrating a semiconductor device including a buried gate according to an embodiment of the present invention.

FIGS. 3A to 3H are cross-sectional views illustrating a method for fabricating a semiconductor device including a buried gate according to an embodiment of the present invention.

FIGS. 4A and 4B are cross-sectional views illustrating an alternative embodiment of the gate-insulating film etching process shown in FIG. 3C.

### DETAILED DESCRIPTION

Exemplary embodiments of the present invention be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. It should be readily understood that the meaning of “on” and “over” in the present disclosure should be interpreted in the broadest manner such that not only means “directly on” something but also include the meaning of “on” something with an intermediate feature or a layer therebetween, and that “over” not only means the meaning of “over” something may also include the meaning it is “over” something with no intermediate feature or layer therebetween (i.e., directly on something).

The following embodiments of the present invention provide a semiconductor device including a buried gate and a method for fabricating the same, in which the width of a contact plug may not exceed a predetermined width. For this purpose, in the embodiments of the present invention, a gate insulating film formed on the surface of a mask pattern is removed before sealing films are formed, so that the gate insulating film is not exposed in a contact hole-forming process. Thus, the sidewall of the sealing film coming into contact with the contact plug is aligned with the sidewall of the trench.

FIG. 2 is a cross-sectional view illustrating a semiconductor device including a buried gate according to an embodiment of the present invention.

As shown in FIG. 2, the semiconductor device includes a plurality of trenches 102 formed in a substrate 101, gate electrodes 104 filling portions of trenches 102, a sealing film 105 formed on the gate electrodes 104 to fill the remaining portions of the trenches 102, and contact plugs 108 interposed between the sealing films 105. Herein, the sidewalls of the sealing films 105 contacting with the contact plugs 108 are aligned with the sidewalls of the trenches. In other words, the width of the sealing films 105 may be larger than that of the gate electrodes 104 and may be substantially the same as that of the trench 102. This may prevent the width of the contact plug 108 from exceeding a predetermined width during processes. This will be described in further detail with reference to a fabrication method as described below.

Each of the gate electrodes 104 and the contact plugs 108 may include a metallic film to achieve low-resistance characteristics. The sealing film 105 may include an insulating material. For example, the sealing film 105 may include a nitride film.

In addition, the semiconductor device further include a gate insulating film 103 interposed between the substrate 101 and the gate electrodes 104, source/drain regions 106 formed below the contact plug 108 on the substrate 101, and an ohmic contact layer interposed between the contact plugs 108 and the source/drain regions 106. Herein, in order to align the sidewalls of the sealing films 105 to the sidewalls of the trenches 102, the gate insulating film 103 may be interposed only between the substrate 101 and the gate electrodes 104. The source/drain regions 106 may include an impurity region formed by ion-implanting an impurity into the substrate 101. The ohmic contact layer 107 serves not only to reduce the contact resistance between each of the contact plugs 108 including a metallic film and each of the source/drain regions 106, but also to prevent the metal component of the contact plugs 108 from being diffused to the substrate 101.

In the semiconductor device having the above-described structure, the sidewalls of the sealing films 105 contacting with the contact plugs 108 are aligned with the sidewalls of the trenches, and thus, the width of the contact plugs 108 may not exceed a predetermined width.

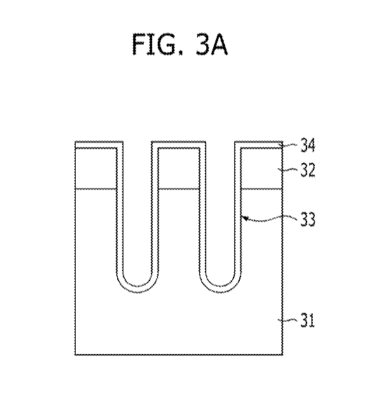

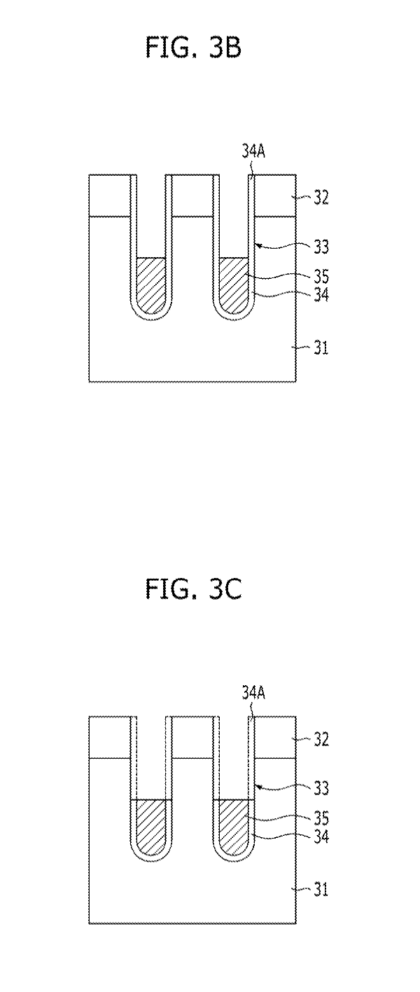

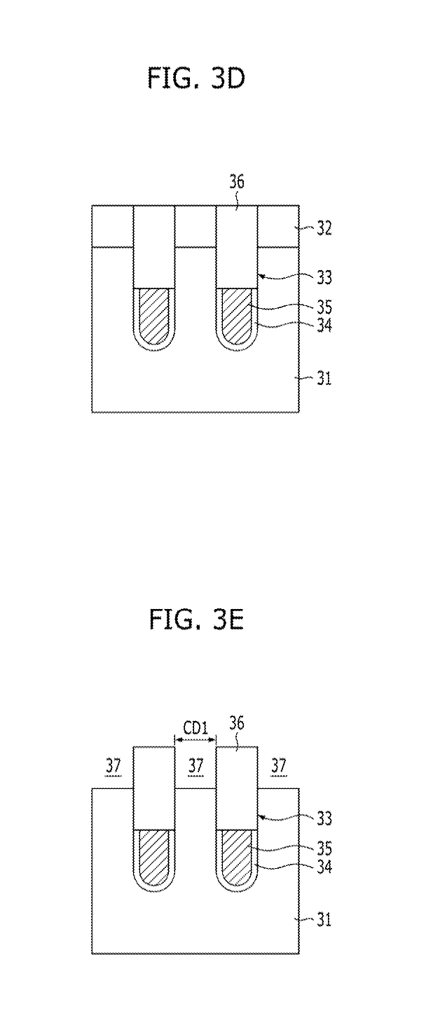

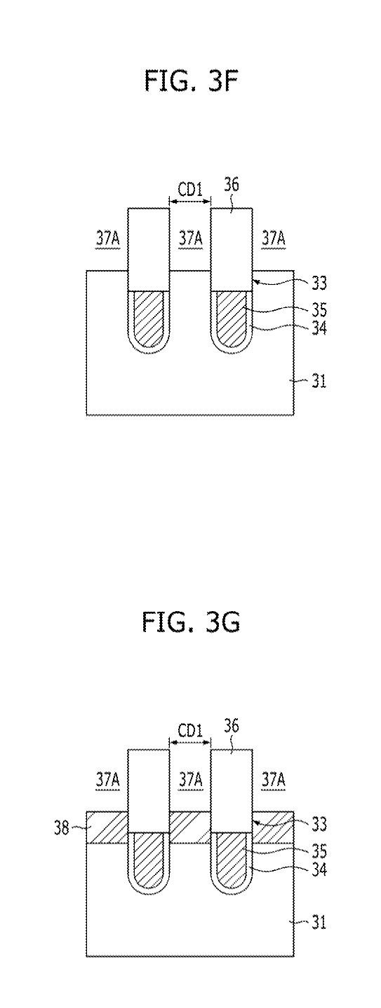

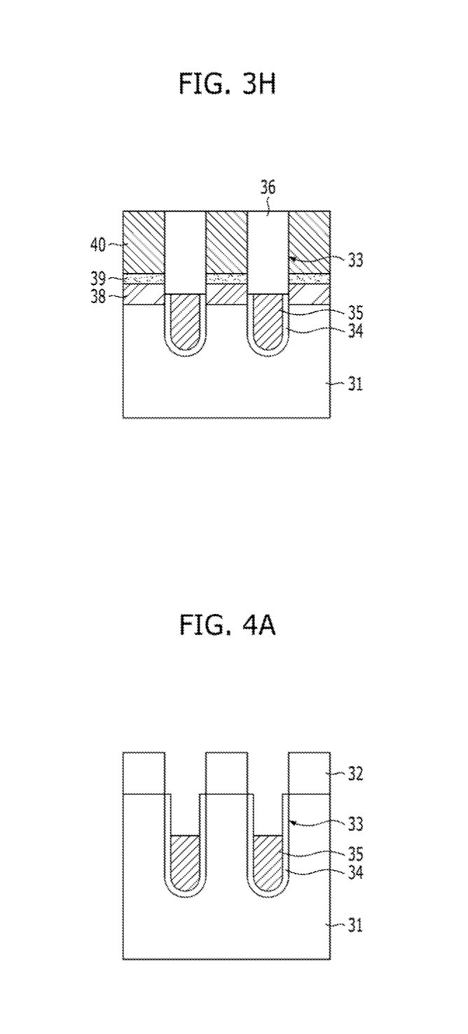

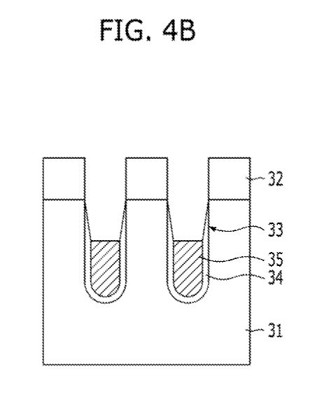

FIGS. 3A to 3H are cross-sectional views illustrating a method for fabricating a semiconductor device including a buried gate according to an embodiment of the present invention. Hereinafter, a method for fabricating the semiconductor device shown in FIG. 2 will be described by way of example. Also, FIGS. 4A and 4B are cross-sectional views illustrating an alternative embodiment of the gate-insulating film etching process shown in FIG. 3C.

As shown in FIG. 3A, a substrate 31 is prepared. The substrate 31 may include a single crystalline material. Also, the substrate 31 may include a silicon-containing material. Thus, the substrate 31 may include single crystalline silicon.

Then, a mask pattern 32 is formed on the substrate 31. The mask pattern 32 may be formed of a single film of an insulating material or a semiconductor material, a stacked film of a plurality of insulating materials or a plurality of semiconductor materials, or a stacked film of an insulating material and a semiconductor material. The insulating material that is used in the present invention may be oxide, nitride, oxynitride, a carbon-containing material (e.g., amorphous carbon) or the like, and the semiconductor material that is used in the present invention may be silicon. For example, the mask pattern 32 may have a stack structure of a silicon oxide film and a polysilicon film.

Then, using the mask pattern 32 as an etch barrier, the substrate 31 is etched to form a plurality of trenches 33. The etching process for forming the trenches 33 may be performed by an anisotropic etching process.

Then, a gate insulating film 34 is formed on the entire surface of the structure including the trenches 33. The gate insulating film 34 may be formed by an oxidation process, such as thermal oxidation or radical oxidation. When the gate insulating film 34 is formed by the oxidation process, the gate insulating film 34 is also formed on the surface of the mask pattern 32 including an insulating material/semiconductor material, in addition to the surface of the trenches 34, because highly relative oxidation is carried out to improve the quality of the gate insulating film 34.

Meanwhile, the gate insulating film 34 may also be formed by a deposition process, such as physical vapor deposition (PVD), chemical vapor deposition (CVD) or atomic layer deposition (ALD).

As shown in FIG. 3B, a gate conductive film is formed on the gate insulating film 34 to fill the trenches 33. The gate conductive film may include a metallic film. As used herein, the term “metallic film” refers to a metal-containing conductive film, such as a metal film, a metal oxide film, a metal nitride film or a metal silicide film.

Then, a planarization process is carried out on the gate conductive film until the mask pattern 32 is exposed. The planarization process may be carried out using chemical mechanical polishing (CMP). In the planarization process, the gate insulating film 34 formed on the mask pattern 32 may be removed.

Then, a surface etching process is carried out on the gate conductive film to form gate electrodes 35 filling portions of the trenches 33. The surface etching process may be performed by an etchback process.

Thus, the gate electrodes 35 for buried gates may be formed. Hereinafter, the gate insulating film 34 exposed by the gate electrodes 35 will be indicated by the reference numeral 34A.

As shown in FIGS. 3C, 4A and 4B, an etching process is carried out to remove a portion or the entire exposed gate insulating film 34A. The etching process may be carried out by wet etching or dry etching.

The etching process is carried out to remove at least the gate insulating film 34A, formed on the surface of the mask pattern 32, among the exposed gate insulating film 34A. Specifically, as shown in FIG. 3C, the exposed gate insulating film 34A may be completely removed. Alternatively, as shown in FIG. 4A, the gate insulating film 34A formed on the surface of the mask pattern 32 may be removed while leaving the gate insulating film 34A formed on the surface of the trenches 33. Alternatively, as shown in FIG. 4B, the etching process may be carried out so that the gate insulating film 34A formed on the surface of the mask pattern 32 may be removed while leaving the gate insulating film 34A formed on the surface of the trenches 33, and the exposed gate insulating film 34A has an inclined surface.

Meanwhile, in order to prevent the previously formed gate electrodes 35 from being damaged in the etching process, the etching process may also be carried out after a protective film (not shown) is formed on the gate electrodes 35. Herein, the protective film is preferably formed on the gate electrodes 35 so that it may fill the trenches 33 while the level of the upper surface thereof is lower than the boundary between the mask pattern 32 and the substrate 31.

As shown in FIG. 3D, an insulating material is deposited on the entire surface of the resulting structure to fill between the trenches 33 and the mask pattern 32, and a planarization process is carried out until the mask pattern 32 is exposed, thereby forming sealing films 36. The planarization process may be carried out using chemical mechanical polishing (CMP).

The sealing films 36 may include a material having an etching selectivity with respect to the mask pattern 32. In addition, the sealing films 36 may include a material that is not etched in an etching process for removing native oxide, that is, a material having an etching selectivity with respect to oxide. For example, the sealing films 36 may include a nitride film.

As described above, after the exposed gate insulating film 34A has been removed, the sealing films 36 are formed so that the sidewall thereof may be aligned with the sidewall of the trenches 33, whereby the width of contact plugs to be formed in a subsequent process may not exceed a predetermined width.

As shown in FIG. 3E, the mask pattern 32 is removed, thereby forming contact holes 37 in which contact plugs are formed. Because the sealing films 36 may include a material having an etching selectivity different from the mask pattern 32, the sealing films 36 are not etched in the process of removing the mask pattern 32. As the contact holes 37 are formed, the sidewalls of the sealing films 36 are exposed, and the contact holes 37 have a first width CD1.

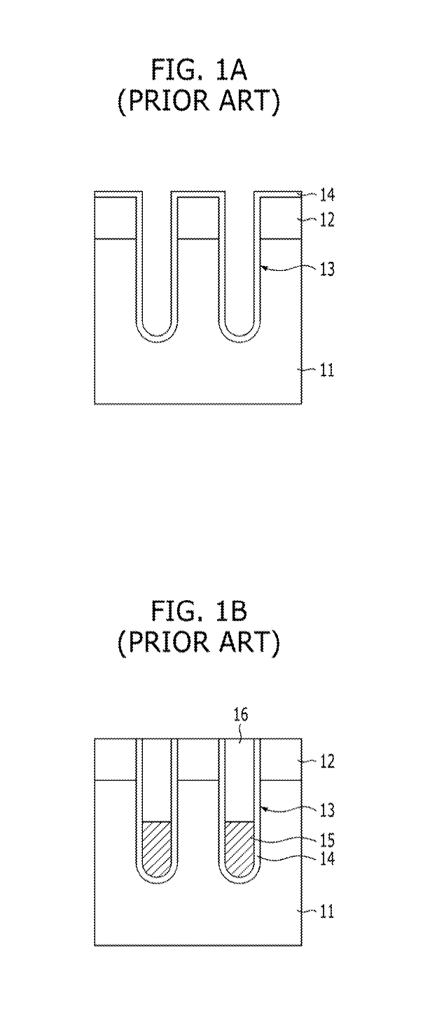

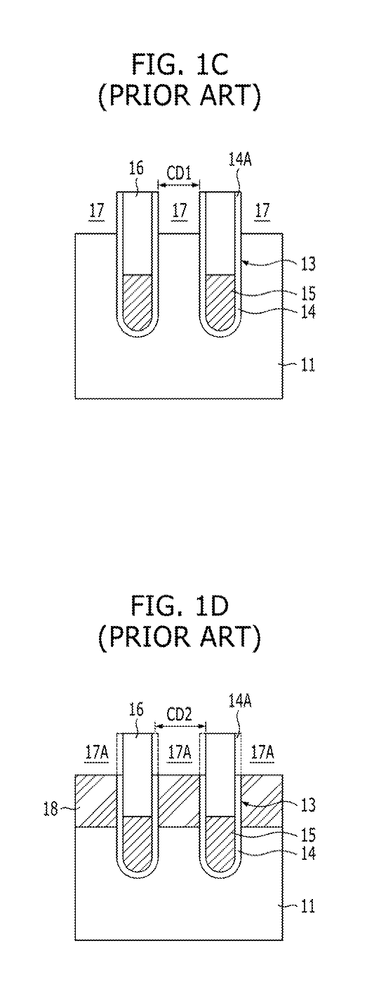

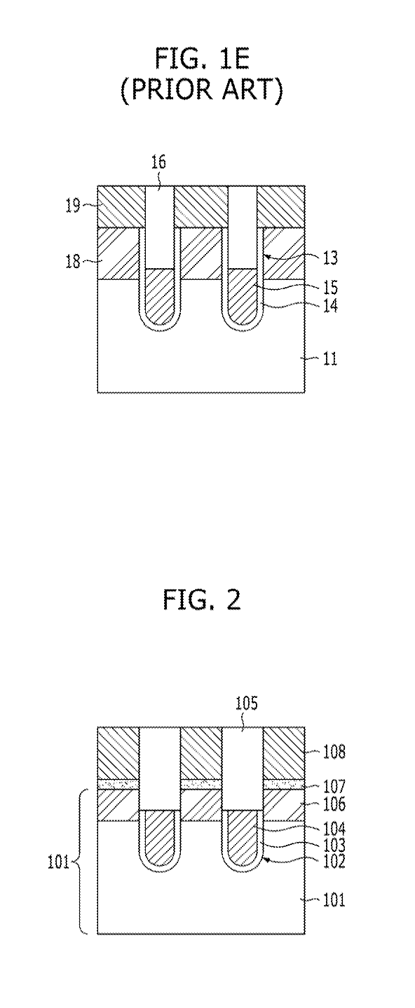

Meanwhile, in the prior art, the gate insulating film formed on the sidewalls of the sealing films were exposed when the contact holes were formed by removing the mask pattern (see FIG. 1C). However, in the embodiment of the present invention, because the exposed gate insulating film 34A is selectively etched before the sealing films 36 are formed, the gate insulating film 34 is not exposed in the process of forming the contact holes 37.

As shown in FIG. 3F, the substrate 31 below the contact holes 37 is recess-etched to extend the contact holes 37 in the depth direction. The recess etching for extending the contact holes 37 may include anisotropic etching, and the amount of etching may be controlled so that the upper surface of the gate electrodes 35 may be located lower than the bottom of the contact holes 37. Hereinafter, the extended contact holes 37 will be indicated by the reference numeral 37A.

The recess etching is carried out in order to provide a space in which an ohmic contact layer for reducing the contact resistance between the source/drain regions and the contact plugs is formed. Also, the recess etching is carried out in order to reduce the thickness of the source/drain regions compared to the prior art to increase the height of the contact plugs having low resistance compared to the source/drain regions, thereby reducing the contact resistance of the semiconductor device.

As shown in FIG. 3G, an impurity is ion-implanted into the substrate 31 below the contact holes 37A to form source/drain regions 38. The source/drain regions 38 may be formed to partially overlap with the gate electrodes 35. The impurity for forming the source/drain regions 38 may be selected depending on the characteristics of the semiconductor device and may be an N-type impurity, such as phosphorus (P) or arsenic (As), or a P-type impurity such as boron (B).

Then, a cleaning process is carried out to remove native oxide from the surface of the substrate 31 before contact plugs are formed. The cleaning process may be carried out using BOE (buffered oxide etchant) or dilute HF. According to the embodiment of the present invention, the sealing films 36 provide the sidewalls of the contact holes 37A, and thus, the width of the contact holes 37A may be maintained at a predetermined width (first width CD1).

As shown in FIG. 3H, an ohmic contact layer 39 is formed by carrying out a series of processes for forming a metal-containing film (not shown) of a specific thickness along the surface of the structure including the contact holes 37A, annealing the resulting structure to form a metal silicide film on the surface of the source/drain regions 38, and removing an unreacted portion of the metal-containing film.

The metal-containing film may contain a metal such as a semiprecious metal or a refractory metal. Specifically, metal-containing film may contain one of cobalt (Co), titanium (Ti), tantalum (Ta), nickel (Ni) tungsten (W), platinum (Pt) and palladium (Pd). The annealing process may be a rapid thermal annealing process and may be carried out at various temperatures depending on the kinds (or materials) of metal-containing film and a material of substrate 31. In addition, the unreacted metal-containing film may be prepared using a mixture of sulfuric acid (H₂SO₄) and hydrogen peroxide (H₂O₂).

Then, a conductive material is applied to the entire surface of the substrate 31 so as to fill the contact holes 37A, and a planarization process is carried out until the sealing films 36 are exposed, thereby forming contact plugs 40. The planarization process may be carried out using chemical mechanical polishing. The contact plugs 40 may have a metallic film to reduce the contact resistance of the semiconductor device.

According to the above-described embodiments of the present invention, before the sealing films 36 are formed, the exposed gate insulating film 34A is removed, particularly the exposed gate insulating film 34A formed on the surface of the mask pattern 32, may be removed. This may prevent the width of the contact plugs 40 from exceeding a predetermined width. Thus, the device characteristics may not deteriorate due to an increase in the electrical interference (e.g., parasitic capacitance) between the adjacent contact plugs 40. In addition, a short circuit may be prevented from occurring between the adjacent contact plugs 40. Furthermore, a decrease in the overlay margin between the contact plugs 40 and structures connected thereto may be prevented. For reference, the decrease in the overlay margin means that a bit line or a storage node is not connected to the desired contact plug 40, but is connected to another contact plug 40 adjacent to the desired contact plug 40.

As described above, according to the present invention, before the sealing films are formed, the gate insulating film formed on the mask pattern is removed. Accordingly, the sealing films may be formed to have a width wider than that of the gate electrode, thus preventing the width of the contact plugs from exceeding a predetermined width during processes.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a plurality of trenches over a substrate;
forming a gate insulating film in each of the plurality of trenches;
forming a plurality of gate electrodes filling portions of the plurality of trenches;
removing an exposed gate insulating film formed over each of the plurality of gate electrodes in each of the plurality of the trenches;
forming a plurality of sealing films filling remaining portions of the plurality of trenches; and
forming a plurality of contact plugs over the substrate between the trenches.

2. The method of claim 1, wherein the method further comprising:
forming a mask pattern over the substrate to form the plurality of trenches in the substrate.

3. The method of claim 2, wherein removing the exposed gate insulating film comprises removing the exposed portion of the gate insulating film formed over the mask pattern.

4. The method of claim 3, wherein the sealing films comprise a material having an etching selectivity different from the mask pattern and the oxide.

5. The method of claim 2, wherein the method further comprising:
forming contact holes by removing the mask pattern the after forming the sealing films.

6. The method of claim 5, wherein the method further comprising:
recess-etching the substrate below the contact holes to extend the contact holes;
forming source/drain regions in the substrate below the contact holes by ion implantation; and
forming an ohmic contact layer over the source/drain regions.

7. The method of claim 6, wherein forming the ohmic contact layer comprises:
forming a metal-containing film along the surface of the structure including the contact holes;
annealing the metal-containing film to form metal silicide over a surface of the source/drain regions; and
removing an unreacted portion of the metal-containing film,

8. The method of claim 1, wherein the method further comprising:
carrying out a cleaning process for removing native oxide from the surface of the substrate, before forming the contact plugs.

9. The method of claim 1, wherein the contact plugs comprise a metallic film.
